(19) United States
(12) Patent Application Publication
(10) Pub. No.: US 2024/0355929 A1
(43) Pub. Date: Oct. 24, 2024

(54) DUAL GATE STRUCTURE FOR MEMORY DEVICE

(71) Applicant: APPLIED MATERIALS, INC., Santa Clara, CA (US)

(72) Inventors: Arvind Kumar, Austin, TX (US); Mahendra Pakala, Saratoga, CA (US); Sanjeev Manhas, Roorkee (IN); Imtiyaz Ahmad Khan, Tanda (IN)

(21) Appl. No.: 18/634,109

(22) Filed: Apr. 12, 2024

Related U.S. Application Data
(60) Provisional application No. 63/460,581, filed on Apr. 19, 2023.

(51) Int. Cl. H01L 29/786; H01L 29/06; H01L 29/423; H01L 29/49; H01L 29/66; H01L 29/775; H10B 12/00

(52) U.S. Cl. CPC H01L 29/78645; H01L 29/0673; H01L 29/42392; H01L 29/4908; H01L 29/495; H01L 29/66439; H01L 29/775; H01L 29/78696; H10B 12/05; H10B 12/315; H10B 12/485

(57) ABSTRACT

A memory device including at least one transistor having a dual gate structure comprising a first gate metal and a second gate metal, wherein the first gate metal has a work function of less than 4.55 eV and the second gate metal has a work function greater than 4.55 eV. A method of forming the memory device is also provided.

### CROSS REFERENCE TO RELATED APPLICATION(S)

The present application claims priority to U.S. Provisional Patent Application No. 63/460,581 filed on Apr. 19, 2023, the contents of which are incorporated in its entirety.

### TECHNICAL FIELD

Embodiments of the present disclosure generally relate to electronic device fabrication. Particularly, embodiments of the present disclosure relate to a memory device including at least one transistor having a dual gate structure.

### BACKGROUND

Memory devices are formed using a variety of materials. It is beneficial for the memory devices (e.g., dynamic random access memory (DRAM)) to have a low or non-existent leakage current. Current two-dimensional (2D) DRAM technology has reached a scaling limit. Accordingly, three-dimensional (3D) DRAM devices have been developed to increase memory density and capacity of DRAM. Some 3D memory devices may include nanowire transistors (e.g., gate all around nanowire (GAA NW)) or nanosheet transistors (e.g., gate all around nanosheet (GAA NS)) transistors. However, it has been found that a “floating body effect” may occur in these 3D memory devices including nanosheet transistors or nanowire transistors because a body of the transistors may not contact a ground of the 3D memory devices. A floating body effect is the effect of dependence of the body potential of a transistor realized by the silicon on insulator (SOI) technology on the history of its biasing and the carrier recombination processes. A charge accumulates on the body of the transistor and may cause adverse effects such as triggering of parasitic transistors in the structure and causing off-state leakages, resulting in higher current consumption and in case of DRAM in loss of information from memory cells. The charge also causes a history effect, where the threshold voltage of the transistor depends on its previous states. Ultimately, the floating body effect induces leakage in the storage capacitor, which leads to character degradation of the memory device. There have been approaches to mitigate the floating body effect in memory devices, but they are insufficient to completely alleviate the problems of the floating body effect.

### SUMMARY

In accordance with an embodiment, a memory device is provided. The memory device may include at least one transistor having a dual gate structure comprising a first gate metal and a second gate metal, wherein the first gate metal has a low work function of less than 4.55 eV and the second gate metal has a high work function greater than 4.55 eV. For example, a low work function may be equal or less than 4.25 eV and a high work function may be equal or greater than 4.75 eV. In another example, a low work function may be less than 4.55 eV and a high work function may be greater than 4.55 eV.

In accordance with another embodiment, a method of manufacturing a memory device is also provided. The method includes forming a first gate on a first portion of a gate oxide using a first metal, wherein the first metal has a low work function of less than 4.55 eV, or less than 4.25 eV; and forming a second gate on a second portion of the gate oxide using a second metal, wherein the second metal has a high work function greater than 4.55 eV, or greater than 4.75 eV.

### BRIEF DESCRIPTION OF THE DRAWINGS

The present disclosure is illustrated by way of example, and not by way of limitation, in the figures of the accompanying drawings in which like references indicate similar elements. It should be noted that different references to “an” or “one” embodiment in this disclosure are not necessarily to the same embodiment, and such references mean at least one.

FIG. 1 is a diagram of an example portion of a memory device including a dual gate structure, in accordance with some embodiments.

FIGS. 2A-2F represent various stages in formation of a memory device including a gate having a dual work function, in accordance with some embodiments.

FIG. 3 is a graph illustrating ID-VG characteristics for transistors having gates with different gate work functions according to an embodiment.

FIG. 4 is a graph illustrating simulated transient characteristics of storage node voltage with varying bit line (BL) voltage pulses for transistors having gates with different gate work functions according to an embodiment.

### DETAILED DESCRIPTION

Embodiments described herein relate to a memory device including at least one transistor having a dual gate structure including a first gate metal and a second gate metal, wherein each gate metal has different work functions. The first gate metal may have a work function of less than 4.55 eV, and the second gate metal may have a work function greater than 4.55 eV. It has been found that transistors in 3D DRAM devices having a single metal gate suffer from the floating body effect. Accordingly, when dynamic pulsing is applied to such memory devices, the stored voltage over time decreases because of the floating body effect. The dual gate structure used for transistors of 3D memory devices (e.g., 3D DRAM memory devices having GAA NS transistors and/or GAA NW transistors) in accordance with embodiments of the present disclosure largely or completely eliminate the floating body effect because the dual gate has been found to eliminate the dynamic retention degradation of the storage node. The dual gate structure according to embodiments employs a dual word line metal (e.g., that includes a first metal for a first portion of a transistor and a second metal for a second portion of the transistors that has a different work function from the first metal). Transistors of GAA DRAM devices and other memory devices (e.g., other 3D memory devices) having the dual gate structure with the dual word line (WL) metals having different work functions has been shown in experiments to completely eliminate dynamic refresh degradation that such devices otherwise suffer due to the floating body effect as described herein.

To achieve the dual gate structure of the present disclosure, two different gate metals are incorporated. The inventors have found that the work function of the gate metals, when chosen carefully, is effective in preventing the floating body effect in a memory device. In embodiments, the first gate metal of the dual gate structure has a first work function and the second gate metal of the dual gate structure has a second work function that is higher than the first work function. In embodiments, a first gate metal of the dual gate structure may have a work function of less than 4.55 eV, while a second gate metal of the dual gate structure may have a work function greater than 4.55 eV to effectively mitigate the floating body effect. In some examples, the first gate metal may have a work function of 4.45 eV, 4.35 eV, 4.25 eV, 4.1 eV, 4.0 eV, or another work function less than 4.55 eV. In some examples, the first gate metal may have a work function of about 3.5 eV to about 4.55 eV, about 3.7 eV to about 4.45 eV, about 3.9 eV to about 4.35, or about 4.0 eV to about 4.25 eV. In some examples, the second gate metal may have a work function of 4.65 eV, 4.75 eV, 4.85 eV, 5.0 eV, 5.25 eV, or another work function above 4.55 eV. In some examples, the second gate metal may have a work function of about 4.6 eV to about 5.5 eV, about 4.75 eV to about 5.6 eV, about 4.85 eV to about 5.4 eV, or about 5.0 eV to about 5.2 eV. In some embodiments, the difference in work function between the first gate metal and the second gate metal is about 0.25 eV, about 0.3 eV, about 0.35 eV, about 0.4 eV, about 0.45 eV, or about 0.5 eV. In other embodiments, the difference in work function between the first gate metal and the second gate metal is greater than 0.25 eV. A difference in the work function between the gate metals may be created by other methods such as ion implantation in the gate electrode, or sandwiching a dipole layer between gate oxide and gate metal. In embodiments, to mitigate the floating body effect the first gate metal having the lower work function is a gate metal closest to a storage node, and the second gate metal having the higher work function is a gate metal closest to a bit line. The first gate metal may include at least one of tantalum (Ta), tungsten (W), titanium nitride (TiN), titanium (Ti), metal alloy such as titanium aluminum (TiAl), or N+ polysilicon. The second gate metal may include at least one of nickel (Ni), cobalt (Co), platinum (Pt), palladium (Pd), ruthenium (Ru), molybdenum (Mo), or another suitable alloy.

The memory device may further include a bit line that contacts the second gate metal and a storage node that contacts the first gate metal. It has been found that to effectively eliminate or mitigate the floating body effect, the gate metal contacting or near the bit line should have a higher work function than the gate metal contacting or near the storage node. The inventors have found that if the gate metal contacting the storage node has a higher work function than the gate metal contacting the bit line, then a floating body effect will still occur.

In embodiments, the first gate metal and the second gate metal may be disposed on a spacer, wherein the first gate metal extends over about 50% of the spacer, and wherein the second gate metal extends over a remaining area of the spacer. In some embodiments, the spacer may be a gate insulator. In an embodiment, the first gate metal and the second gate metal do not overlap. In some embodiments, the first gate metal and the second gate metal may overlap.

In some embodiments, the memory device may include a channel on each side of the spacer. In some embodiments, the channel may have a thickness of about 10 nm to about 25 nm, or about 5 nm to about 40 nm.

In some embodiments, the memory device may be a dynamic random access memory (DRAM).

In an embodiment, the memory device may include a scaffold including a plurality of alternating layers of silicon (Si) and silicon germanium (SiGe) and at least one nitride layer.

In embodiments described herein, a method of manufacturing a memory device may include forming a first gate on a first portion of a gate oxide using a first metal, wherein the first metal has a work function of less than 4.55 eV; and forming a second gate on a second portion of the gate oxide using a second metal, wherein the second metal has a work function greater than 4.55 eV. In some examples, the first metal may have a work function of 4.45 eV, 4.35 eV, 4.25 eV, 4.1 eV, 4.0 eV, or another work function less than 4.55 eV. In some examples, the first metal may have a work function of about 3.5 eV to about 4.55 eV, about 3.7 eV to about 4.45 eV, about 3.9 eV to about 4.35, or about 4.0 eV to about 4.25 eV. In some examples, the second metal may have a work function of 4.65 eV, 4.75 eV, 4.85 eV, 5.0 eV, 5.25 eV, or another work function above 4.55 eV. In some examples, the second metal may have a work function of about 4.6 eV to about 5.5 eV, about 4.75 eV to about 5.6 eV, about 4.85 eV to about 5.4 eV, or about 5.0 eV to about 5.2 eV. In some embodiments, the difference in work function between the first metal and the second metal is about 0.25 eV, about 0.3 eV, about 0.35 eV, about 0.4 eV, about 0.45 eV, or about 0.5 eV. In other embodiments, the difference in work function between the first metal and the second metal is greater than 0.25 eV.

As used herein, “substrate” refers to a surface, or portion of a surface, upon which a process acts. It will also be understood by those skilled in the art that reference to a substrate can also refer to only a portion of the substrate unless the context clearly indicates otherwise. Additionally, references to depositing on a substrate can mean both a bare substrate and a substrate with one or more films or features deposited or formed thereon. Examples of substrates include wafers (e.g., patterned or unpatterned wafers such as Si wafers) and so on.

A substrate as used herein may also refer to any substrate or any material surface formed on a substrate surface on which film processing is performed during a fabrication process. For example, a substrate surface on which processing can be performed may include materials such as silicon, silicon dioxide, strained silicon, silicon on insulator (SOI), carbon doped silicon oxides, silicon nitride, doped silicon, silicon germanium, and any other materials such as metals, metal nitrides, metal alloys, and other conductive materials, depending on the application. Substrates include, without limitation, semiconductor wafers, displays, and so on.

Substrates may be exposed to a pretreatment process to polish, etch, reduce, oxidize, hydroxylate (or otherwise generate or graft target chemical moieties to impart chemical functionality), anneal and/or bake the substrate surface. In addition to layer processing steps performed directly on the surface of the substrate itself, in the present disclosure, any of the layer processing steps disclosed may also be performed on an underlayer formed on the substrate as disclosed in more detail below, and the term “substrate surface” is intended to include such underlayer as the context indicates.

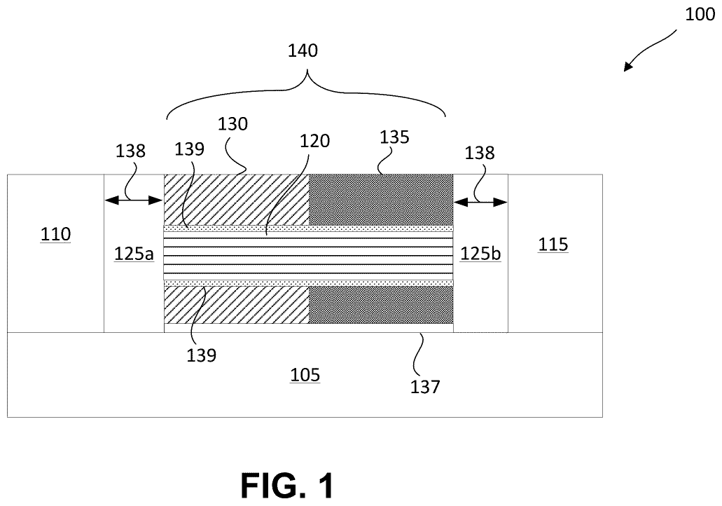

Referring now to the figures, FIG. 1 is a cross-sectional view of a portion of a memory device 100 including a transistor having a dual gate structure 140 according to embodiments of the present disclosure. The memory device 100 of the present disclosure may be a variety of memory devices, including a dynamic random access memory (“DRAM”) device that includes gate all around (GAA) field effect transistors (FETs) such as GAA NW FETs and/or GAA NS FETs. There are two types of GAAFETs: nanowire (NW) FETs having the same width (WNW) and thickness of the channels, and nanosheet (NS) FETs having wide width (WNS) but the fixed thickness of the channels as 5 nm.

The memory device 100 includes a substrate 105. The substrate 105 may be made of silicon, silicon oxide, strained silicon, silicon on insulator (SOI), carbon doped silicon oxides, silicon nitride, doped silicon, silicon germanium, and any other materials such as metals, metal nitrides, metal alloys, and other conductive materials.

The memory device 100 includes a transistor having a dual gate structure 140 that is formed on the substrate 105. In embodiments, the transistor includes a gate with a dual work function, where the gate has a first work function proximate to a source (e.g., storage node 110, or bit line 115) and a second work function proximate to a drain (e.g., storage node 110, or bit line 115). The transistor with the dual work function (e.g., achieved by constructing the gate to have a first gate metal in a first region and a second gate metal in a second region) reduces or eliminates the floating body effect or floating body effect induced retention degradation for a transistor such as a GAA FET.

In some embodiments, the transistor having the dual gate structure 140 is formed on a full bottom dielectric isolation (BDI) layer 137. The full bottom BDI layer 137 may provide improved process control due to full bottom dielectric isolation (FBDI) in a source/drain region of the transistor. In one embodiment, the full bottom isolation BDI layer 137 comprises a high-concentration SiGe layer at a bottom of the transistor (e.g., at a bottom of a Si, SiGe nanosheet stack). The dual gate structure 140 of the transistor includes a first gate metal 130 and a second gate meal 135. The first gate metal 130 is proximate to a storage node 110 of the memory device 100 and the second gate metal 135 is proximate to a bit line or capacitor 115 of the memory device 100. In embodiments, the storage node 110 may be a source and may include a source doping and the bit line 115 may be a drain and may include a drain doping. In another embodiment, the storage node 110 may be a drain and may include a drain doping and the bit line 115 may be a source and may include a source doping.

In embodiments, a channel 125a separates the first gate metal 130 from the storage node 110 and a channel 125b separates the second gate metal 135 from the bit line 115. Increasing the length 138 of the channels 125a-b (e.g., of spacers between the storage node and the gate and between the bit line and the gate) can reduce the floating body effect for the transistor, but at the expense of reducing current. In embodiments, the first gate metal 130 and second gate metal 135 are formed on, under, and/or around a stack of alternating layers of SiGe and Si, referred to as a nanosheet stack 120.

The transistor includes a spacer (e.g., gate insulator) 139 that separates the nanosheet stack 120 from the first gate metal 130 and the second gate metal 135, such that the first and second gate metals 130, 135 are applied to be in contact with the nanosheet stack 120. The spacer 139 may be a gate insulator, or dielectric such as an oxide or a nitride (e.g., SiO₂ or SiN). In an embodiment, the first gate metal 130 has a work function of less than 4.55 eV. In some examples, the first gate metal 130 may have a work function of 4.45 eV, 4.35 eV, 4.25 eV, 4.1 eV, 4.0 eV, or another work function less than 4.55 eV. In some examples, the first gate metal 130 may have a work function of about 3.5 eV to about 4.55 eV, about 3.7 eV to about 4.45 eV, about 3.9 eV to about 4.35, or about 4.0 eV to about 4.25 eV. The first gate metal may include at least one of Ta, W, TiN, Ti, or N+ polysilicon. In an embodiment, the second gate metal 135 has a work function greater than 4.55 eV. In some examples, the second gate metal 135 may have a work function of 4.65 eV, 4.75 eV, 4.85 eV, 5.0 eV, 5.25 eV, or another work function above 4.55 eV. In some examples, the second gate metal 135 may have a work function of about 4.6 eV to about 5.5 eV, about 4.75 eV to about 5.6 eV, about 4.85 eV to about 5.4 eV, or about 5.0 eV to about 5.2 eV. The second gate metal 135 may include at least one of Ni, Co, Pt, Pd, Ru, or Mo. In some embodiments, the difference in work function between the first gate metal and the second gate metal is about 0.25 eV, about 0.3 eV, about 0.35 eV, about 0.4 eV, about 0.45 eV, or about 0.5 eV. In other embodiments, the difference in work function between the first gate metal and the second gate metal is greater than 0.25 eV. In an embodiment, the first gate metal 130 and the second gate metal 135 are disposed on the spacer 139. The first gate metal 130 may extend over about 50% of the spacer 139 (and about 50% of the nanosheet stack 120 of Si and SiGe alternating layers). In another embodiment, the first gate metal 130 may extend over about 30% to about 65% of the spacer 139 (and about 30% to about 65% of the nanosheet stack 120 of Si and SiGe alternating layers). The second gate metal 135 may extend over the remaining area of the spacer 139 (and of the nanosheet stack 120) that does not include the first gate metal 130. In some embodiments, the first gate metal 130 and the second gate metal 135 do not overlap. In other embodiments, the first gate metal 130 and the second gate metal 135 overlap about 5% to about 15%.

As indicated above, the memory device 100 includes channels 125a, 125b on each side of the dual gate structure 140 (e.g., including nanosheet stack 120, spacer 139, first gate metal 130, and second gate metal 135). The channel 125a, 125b may have a length (e.g., distance between storage node/bit line and dual gate structure 140) of about 5 nm to about 40 nm, or about 10 nm to about 25 nm. The channels 125a, 125b can be doped or undoped. If doped, the channels 125a, 125b can be doped with any group III or group V elements.

The memory device 100 may include a storage node 110. The storage node 110 may include a doped polysilicon in embodiments (e.g., having an n or p doping), TiN or W in other embodiments. The memory device 100 may also include a bit line 115. The bit line 115 may also be doped polysilicon (e.g., having an n or p doping).

In an embodiment, the first gate metal 130 contacts or is near the storage node 110 through channel 125a, and the second gate metal 135 contacts or is near the bit line 115 through channel 125b. It is understood that the gate metal contacting/near the storage node 110 has a lower work function than the gate metal contacting/near the bit line 115.

In some embodiments, the memory device may be a dynamic random access memory (“DRAM”), which may be a 3D DRAM having GAA NS FETs or GAA NW FETs.

FIG. 1 illustrates a 2D structure (e.g., a horizontal transistor) having a gate with a dual work function for simplicity of explanation. However, it should be understood that the principals described with reference to a 2D structure apply even more beneficially to a 3D structure (e.g., such as 3D DRAM that includes vertical transistors).

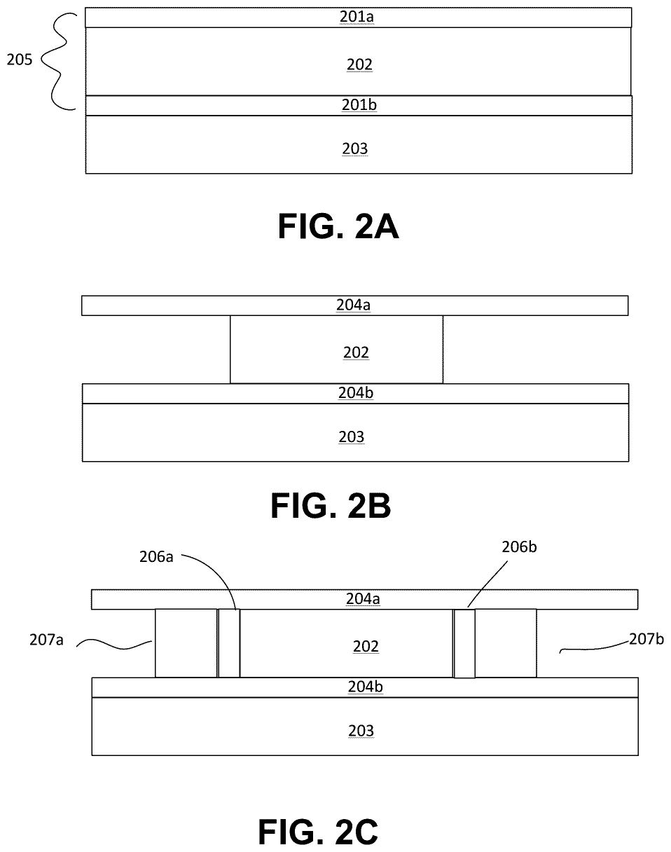

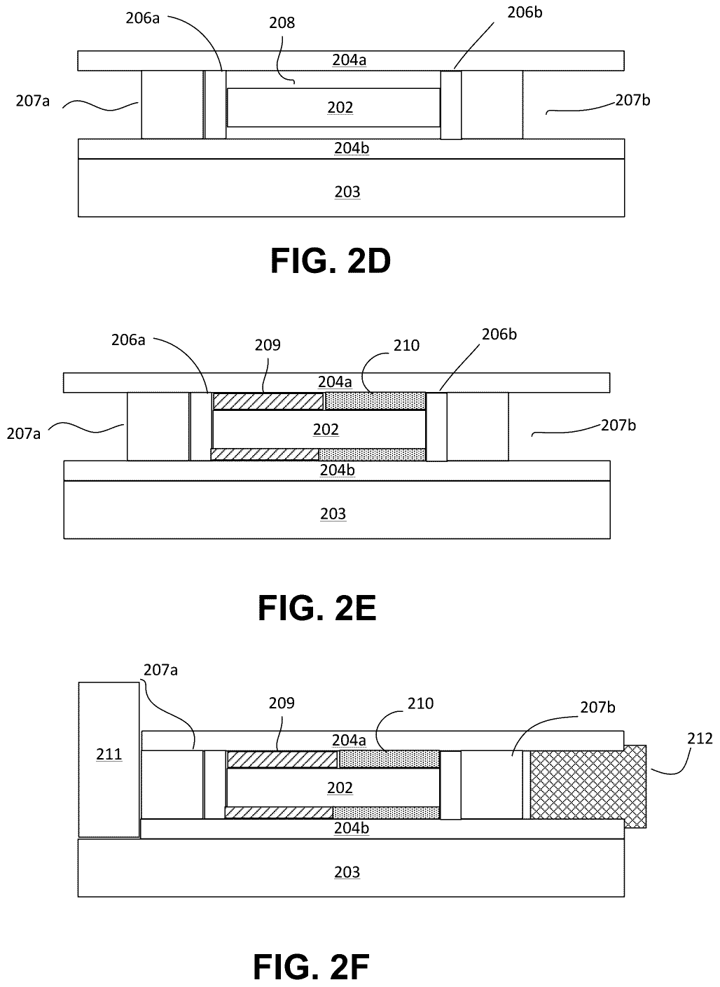

FIGS. 2A-2F represent various stages in formation of a memory device including a gate having a dual work function, in accordance with some embodiments.

In FIG. 2A, a memory device 200 including a substrate 203 is received having a stack of silicon (Si) 202 and silicon germanium (SiGe) 201a, 201b layers. The stack of Si and SiGe layers may be patterned into a lattice structure, and may be referred to as a nanosheet stack 205. It should be understood that even though two SiGe layers and one Si layer is illustrated in FIG. 2A, that the memory device is not limited to these layers. Rather, the memory device may include several layers, such as about 100 layers of alternating Si and SiGe layers. For purposes of illustration and simplicity of explanation, only one transistor having a dual gate structure (e.g., dual work function) is being described herein. It should be understood that the memory access device may include multiple transistors as described herein. The multiple transistors may be stacked on each other to reach a target height for the memory device and/or may be arranged side-by-side.

In FIG. 2B a region of the SiGe layers are removed from the stack and are replaced with a nitride layer 204a, 204b, respectively to act as a spacer. Additionally, the Si layer 202 may be etched. The etching may be achieved by any method as known by one of skill in the art.

In FIG. 2C, a spacer 206a, 206b is formed on either side of the nanosheet stack, such as the Si layer 202, as shown in FIG. 2C, and a storage node 207b and bit line 207a are created on either side of the spacer. The storage node and bit line may be an epitaxial layer, a polysilicon layer, a doped polysilicon layer, and so on. The spacer may be undoped or a low doped polysilicon layer.

In FIG. 2D, a channel 208 is formed on two sides of the nanosheet stack, such as the Si layer 202. The channel 208 is formed so that there is space to form a spacer of an oxide, nitride or other dielectric, and space to add the metal gate (e.g., the dual work function gate having a first metal and a second metal). After forming the channels 208, the spacer may be formed, and the dual gate structure including a first and second metal can be deposited as is shown in FIG. 2E, with the spacer separating the gate from the nanosheet stack. To apply the gate, a first photoresist may be deposited, patterned (e.g., via photolithography), and etched to reveal an area to which a first metal (M1) 210 will be deposited. The first metal 210 may then be deposited. The first photoresist may be removed, and a second photoresist may be deposited, patterned, and etched to reveal a second area to which the second metal (M2) 209 will be deposited. After depositing the second metal 209, the second photoresist may be removed.

In some embodiments, the spacer may include a sacrificial layer. In some embodiments, the sacrificial layer may be a polymer layer, a nitride layer, or a silicon layer. In some embodiments, a gate oxide layer may be formed on the spacer of the transistor. The gate oxide may be dielectric. In one embodiment, after performing the photolithography process associated with formation of one of the gate metals, a portion of the sacrificial layer may be removed. After removing the sacrificial layer, a first metal may then be applied to the area. The first metal fills in the space that was removed in the sacrificial layer. In an embodiment, the first gate metal or first metal may be applied to the memory device such that it contacts the entirety of the spacer/gate insulator. In an embodiment, the first gate metal/metal may be applied such that it contacts only a portion of the spacer/gate insulator. For example, the first gate metal/metal may be applied to about 30% to about 65% of the spacer/gate insulator. After the first metal is applied, then a protective layer can be formed. Once the protective layer is formed, the second metal is then applied to the unprotected area. As can be seen in FIG. 2E, the first metal 210 is formed such that it may contact the storage node 207b, while the second metal 209 is formed such that it may contact the bit line 207a.

The first metal 210 has a work function of less than 4.55 eV, while the second metal 209 has a work function greater than 4.55 eV. In some examples, the first metal 210 may have a work function of 4.45 eV, 4.35 eV, 4.25 eV, 4.1 eV, 4.0 eV, or another work function less than 4.55 eV. In some examples, the first metal 210 may have a work function of about 3.5 eV to about 4.55 eV, about 3.7 eV to about 4.45 eV, about 3.9 eV to about 4.35, or about 4.0 eV to about 4.25 eV. In some examples, the second metal 209 may have a work function of 4.65 eV, 4.75 eV, 4.85 eV, 5.0 eV, 5.25 eV, or another work function above 4.55 eV. In some examples, the second metal 209 may have a work function of about 4.6 eV to about 5.5 eV, about 4.75 eV to about 5.6 eV, about 4.85 eV to about 5.4 eV, or about 5.0 eV to about 5.2 eV. In some embodiments, the difference in work function between the first metal 210 and the second metal 209 is about 0.25 eV, about 0.3 eV, about 0.35 eV, about 0.4 eV, about 0.45 eV, or about 0.5 eV. In other embodiments, the difference in work function between the first gate metal 210 and the second gate metal 209 is greater than 0.25 eV The first metal may include at least one of Ta, W, TiN, Ti, or N+ polysilicon or an alloy having a work function described herein. The second metal 209 may include at least one of Ni, Co, Pt, Pd, Ru, or Mo or an alloy having a work function described herein.

After the dual gate is formed in FIG. 2E, a capacitor or storage node 212 is then formed at the source node 207b and a bit line 211 is formed at a drain node/bit line compensation (BLC) 207a in FIG. 2F.

### EXAMPLES

The memory device of the present disclosure will now be described herein by the following examples. It is understood that the examples are not to be limiting.

### Example 1: Id-Vg Characteristics of Single and Double Gate Structures

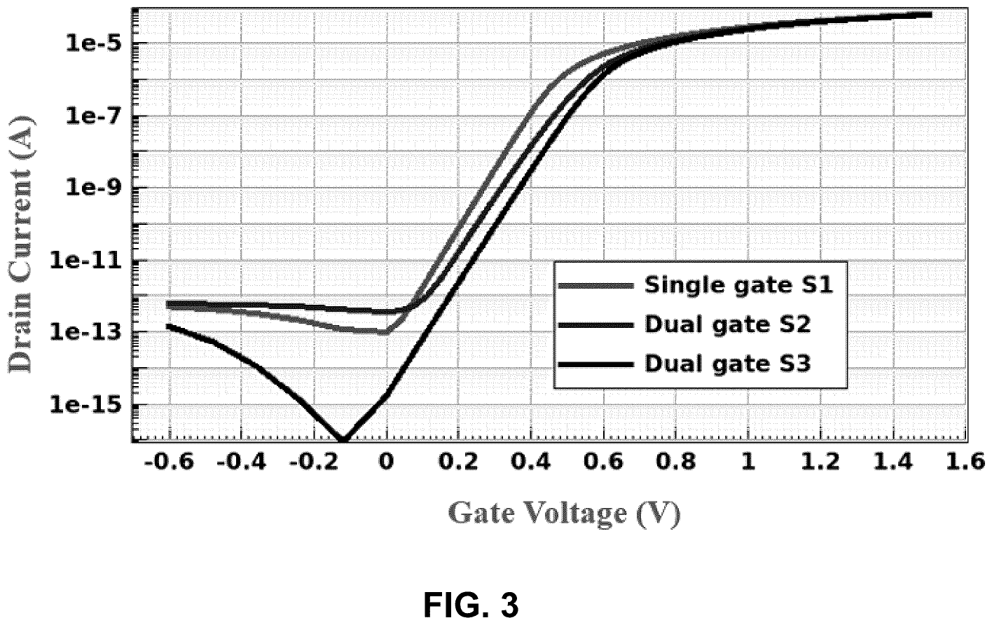

Three sample devices were created in TCAD tool to simulate the Id-Vg characteristics for different gate work functions. In the first sample (S1), a single gate structure was prepared using a single metal. The single metal had a work function of 4.65 eV. In the second sample (S2), a dual gate structure was prepared using two metals, having differing work functions. In the second sample (S2), the metal contacting the storage node had a work function of 4.8 eV, while the metal contacting the bit line had a work function of 4.25 eV. In the third sample (S3), a dual gate structure was prepared using two different metals having different work functions. In the third sample (S3), the metal contacting the storage node had a work function of 4.25 eV, while the metal contacting the bit line had a work function of 4.8 eV. As can be seen in FIG. 3, the third sample (S3), i.e., the double gate with a high work function on the bit line side, resulted in the lowest Ioff current (current when transistor is switched off) and higher Ion current (e.g., current when transistor is switched on). The results of this test are presented in Table 1 below.

TABLE 1

| | Ion Current | Ioff Current | Threshold Voltage |
|---|---|---|---|
| Sample | (A) | (A) | (V) |
| First Sample: Single | 6.48e−5 | 9.80e−14 | 0.41 |
| Gate (S1) | | | |
| Second Sample: Dual | 6.28e−5 | 3.53e−13 | 0.49 |
| Gate (S2) | | | |
| Third Sample: Dual | 6.38e−5 | 1.69e−15 | 0.53 |
| Gate (S3) | | | |

The remaining parameters of the samples are presented in Table 2. It is noted that the parameters were kept constant amongst the three samples, where only the work function was varied in the gate structures described above.

TABLE 2

| Parameter | Value | |
|---|---|---|
| Channel Length | 70 | nm |
| Oxide Thickness | 3.5 | nm |
| Channel Thickness | 20 | nm |
| Channel Width | 50 | nm |
| Channel Doping | 1e15 | cm−3 |
| Source/Drain Extension Length | 30 | nm |
| Source Doping | 1e20 | cm−3 |
| Drain Doping | 5e19 | cm−3 |
| Source/Drain Length | 60 | nm |
| Gate Metal Overlap | 10 | nm |

### Example 2: Effect of Gate on Dynamic Retention Time

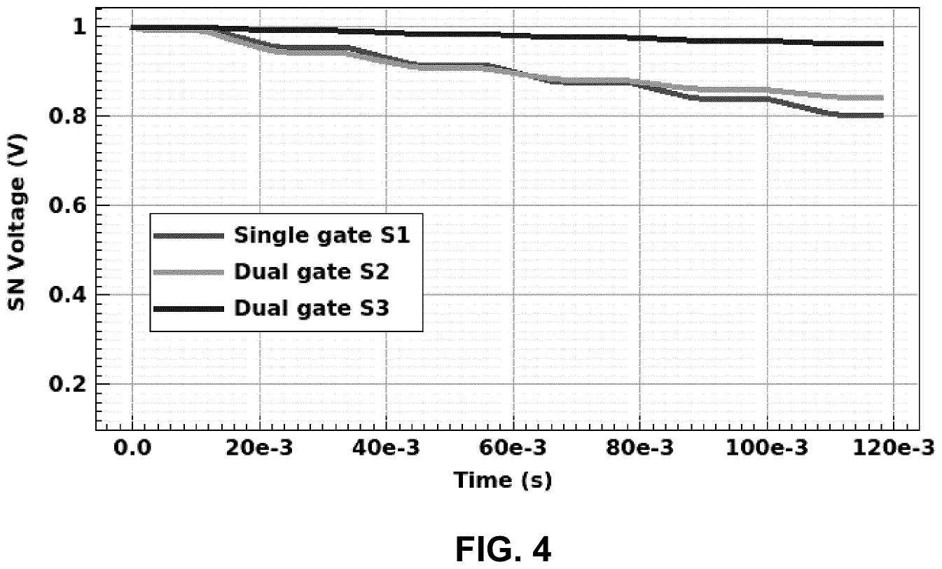

Another test was conducted on the three samples as described in Example 1 to study the storage node voltage of the various gates with varying bit line voltage pulse. The results of this test can be seen in FIG. 4. As can be seen in FIG. 4, the third sample having a dual gate structure with higher work function on the bit line side did not have a floating gate induced storage node reduction because the storage node voltage remained constant over the measured time. In contrast, the storage node voltage of the first sample (single gate) and the second sample (dual gate with low work function on bit line side) began decreasing around the 20e-3 time point and steadily decreased over time, indicating that there was a floating body effect present.

The preceding description sets forth numerous specific details such as examples of specific systems, components, methods, and so forth, in order to provide a good understanding of several embodiments of the present disclosure. It will be apparent to one skilled in the art, however, that at least some embodiments of the present disclosure may be practiced without these specific details. In other instances, well-known components or methods are not described in detail or are presented in simple block diagram format in order to avoid unnecessarily obscuring the present disclosure. Thus, the specific details set forth are merely exemplary. Particular implementations may vary from these exemplary details and still be contemplated to be within the scope of the present disclosure.

Reference throughout this specification to “one embodiment” or “an embodiment” means that a particular feature, structure, or characteristic described in connection with the embodiment is included in at least one embodiment. Thus, the appearances of the phrase “in one embodiment” or “in an embodiment” in various places throughout this specification are not necessarily all referring to the same embodiment. In addition, the term “or” is intended to mean an inclusive “or” rather than an exclusive “or.” When the term “about” or “approximately” is used herein, this is intended to mean that the nominal value presented is precise within ±10%.

Although the operations of the methods herein are shown and described in a particular order, the order of the operations of each method may be altered so that certain operations may be performed in an inverse order or so that certain operation may be performed, at least in part, concurrently with other operations. In another embodiment, instructions or sub-operations of distinct operations may be in an intermittent and/or alternating manner.

It is to be understood that the above description is intended to be illustrative, and not restrictive. Many other embodiments will be apparent to those of skill in the art upon reading and understanding the above description. The scope of the disclosure should, therefore, be determined with reference to the appended claims, along with the full scope of equivalents to which such claims are entitled.

What is claimed is:

1. A memory device, comprising:
at least one transistor having a dual gate structure comprising a first gate metal and a second gate metal, wherein the first gate metal has a first work function and the second gate metal has a second work function that is higher than the first work function.

2. The memory device of claim 1, wherein the first work function is less than 4.55 eV and the second work function is greater than 4.55 eV.

3. The memory device of claim 1, wherein the first gate metal comprises at least one of tantalum (Ta), tungsten (W), titanium nitride (TiN), titanium (Ti), or N+ polysilicon, and wherein the second gate metal comprises at least one of nickel (Ni), cobalt (Co), platinum (Pt), palladium (Pd), ruthenium (Ru), or molybdenum (Mo).

4. The memory device of claim 1, further comprising a bit line that contacts or is near the second gate metal and a storage node that contacts or is near the first gate metal.

5. The memory device of claim 1, wherein the first gate metal and the second gate metal are disposed on a spacer, wherein the first gate metal extends over about 50% of the spacer, and wherein the second gate metal extends over a remaining area of the spacer.

6. The memory device of claim 5, wherein the first gate metal and the second gate metal do not overlap.

7. The memory device of claim 5, wherein the first gate metal and the second gate metal overlap about 10% to about 20%.

8. The memory device of claim 5, further comprising a channel on each side of the spacer, wherein the channel has a thickness of about 5 nm to about 40 nm.

9. The memory device of claim 1, wherein the memory device is a dynamic random access memory (DRAM).

10. The memory device of claim 1, further comprising:
a scaffold comprising a plurality of alternating layers of silicon (Si) and silicon germanium (SiGe); and
at least one nitride layer.

11. A method of manufacturing a memory device, comprising:
forming a first gate on a first portion of a gate oxide using a first metal, wherein the first metal has a work function of less than 4.55 eV; and
forming a second gate on a second portion of the gate oxide using a second metal, wherein the second metal has a work function greater than 4.55 eV.

12. The method of claim 11, wherein the first metal comprises at least one of tantalum (Ta), tungsten (W), titanium nitride (TiN), titanium (Ti), or N+ polysilicon.

13. The method of claim 11, wherein the second metal comprises at least of nickel (Ni), cobalt (Co), platinum (Pt), palladium (Pd), ruthenium (Ru), or molybdenum (Mo).

14. The method of claim 11, further comprising forming a bit line that contacts or is near the second metal and forming a storage node that contacts or is near the first metal.

15. The method of claim 11, further comprising forming the first gate and the second gate on a spacer.

16. The method of claim 15, wherein the first gate extends over about 50% of the spacer, and wherein the second gate over a remaining area of the spacer.

17. The method of claim 15, further comprising forming a channel on each side of the spacer.

18. The method of claim 17, wherein the channel has a thickness of about 5 nm to about 40 nm.

19. The method of claim 11, wherein the memory device is a DRAM.

20. The method of claim 11, wherein the gate oxide comprises a dielectric layer.
